(19) United States
(12) Patent Application Publication
(10) Pub. No.: US 2025/0081682 A1
(43) Pub. Date: Mar. 6, 2025

(54) LIGHT-EMITTING DEVICE AND MANUFACTURING METHOD THEREOF AND DISPLAY SCREEN

(71) Applicant: Tianjin Sanan Optoelectronics Co., Ltd., Tianjin (CN)

(72) Inventors: Jing WANG, Tianjin (CN); Yang YANG, Tianjin (CN); Qingpo ZHANG, Tianjin (CN); Jun JIANG, Tianjin (CN); Chihhsien WANG, Tianjin (CN); Huanshao KUO, Tianjin (CN)

(73) Assignee: Tianjin Sanan Optoelectronics Co., Ltd., Tianjin (CN)

(21) Appl. No.: 18/820,187

(22) Filed: Aug. 29, 2024

(30) Foreign Application Priority Data
Aug. 31, 2023 (CN) 202311122727.2

(51) Int. Cl. H01L 33/46; H01L 33/00; H01L 33/24; H01L 33/30

(52) U.S. Cl. CPC H10H 20/841; H10H 20/013; H10H 20/821; H10H 20/034; H10H 20/824

(57) ABSTRACT

Disclosed are a light-emitting device, a manufacturing method thereof, and a display screen. In the light-emitting device, an isolation trench is formed from one side of the first semiconductor layer to one side of the second semiconductor layer. A reflective structure is formed on the side wall of the isolation trench and the first semiconductor layer, which helps to reduce light loss and improving the light output efficiency of the device. The isolation trench does not completely penetrate the second semiconductor layer, so that the second semiconductor layer located on the light output surface side is a continuous and uninterrupted integrated structure, and a surface thereof remains flat so that the transparent conductive layer has a flat structure, improving the overall coverage of the transparent conductive layer. The present invention has no cracks, peeling problems, thus improving the electrical stability of the device and increasing the reliability thereof.

### CROSS-REFERENCE TO RELATED APPLICATION

This application claims the priority benefit of China application serial no. 202311122727.2, filed on Aug. 31, 2023. The entirety of the above-mentioned patent application is hereby incorporated by reference herein and made a part of this specification.

### BACKGROUND

### Technical Field

The present disclosure relates to the technical field of semiconductor devices and devices, and in particular to a light-emitting device, a manufacturing method thereof and a display screen.

### Description of Related Art

As the AR/VR market gradually expands, there is also a growing demand for applications of Micro LED in AR/VR. Moreover, when application products are designed to be smaller and lighter, it is required that the size of Micro LED be decreased as well. Wafer size needs to be reduced to 5 μm, 2 μm or even below 2 μm. There are generally two application methods for the application of Micro LED full-color screens: one is forming single wafer of R, G, and B colors into arrays to form an RGB full-color screen; the other is forming R, G, and B colors into single-color screens separately, and then forming the single-color screens into a full-color screen by screen mixing. The first way of arranging RGB single wafers brings great challenges when it comes to wafer transfer, positioning, packaging, quality inspection and repair of bad pixels, and the difficulty is even greater when the wafer size is less than 2 μm. On the contrary, the way of forming a full-color screen by screen mixing described in another application method is more operable.

However, the micro LED monochromatic screen in the conventional technology has a metal electrode on the bottom of the wafer, which inevitably has a problem of light absorption. When the chip size becomes smaller and smaller, almost all the bottom area is occupied by metal electrodes, leaving no space for a reflective layer, which causes a great loss in brightness. Secondly, when the chips are separated from the front of the wafer, the gap filling process between chips is difficult, and different levels of height differences are prone to occur. As a result, it is difficult to ensure the full coverage of ITO, and cracks might occur easily.

### SUMMARY

In view of the above-mentioned defects in the structure and formation process of monochromatic screens in the conventional technology, the present disclosure provides a light-emitting device, a manufacturing method thereof, and a display screen to solve one or more of the above-mentioned problems.

An embodiment of the present application provides a light-emitting device, which at least includes:
an epitaxial structure, wherein the epitaxial structure at least includes a first semiconductor layer structure, an active layer, and a second semiconductor layer structure that are stacked in sequence;
a plurality of isolation trenches, wherein the isolation trenches penetrate the first semiconductor layer structure, the active layer and part of the second semiconductor layer structure along the stacking direction of the epitaxial structure, and areas between the adjacent isolation trenches serve as a plurality of light-emitting areas, one side of the second semiconductor layer structure is the light output surface of the light-emitting device, and one side of the first semiconductor layer structure is the bonding surface;
a first reflective structure, which is located on the sidewall of the isolation trench and the first semiconductor layer structure.

Another embodiment of the present disclosure provides a method for manufacturing a light-emitting device, which includes the following steps:
providing a growth substrate;
growing a first semiconductor layer structure, an active layer, and a second semiconductor layer structure in sequence on the growth substrate to form an epitaxial structure;
bonding the epitaxial layer to a temporary substrate on one side of the second semiconductor layer structure;
removing the growth substrate to expose the first semiconductor layer structure;
etching the epitaxial structure on one side of the first semiconductor layer structure, wherein the first semiconductor layer structure, the active layer and part of the second semiconductor layer structure are etched in sequence to form a plurality of isolation trenches, and areas between adjacent isolation trenches serve as a plurality of light-emitting areas, one side of the second semiconductor layer structure is the light output surface of the light-emitting device, and one side of the first semiconductor layer structure is the bonding surface;
forming the first reflective structure on one side of the first semiconductor layer structure, wherein the first reflective structure is formed on the sidewall of the isolation trench and on the first semiconductor layer structure.

Another embodiment of the present disclosure provides a display screen, which includes:
at least one light-emitting device, wherein the light-emitting device includes the light-emitting device provided by the disclosure;
a CMOS substrate includes a device layer, wherein the device layer includes several CMOS devices;
a bonding layer, which is located between the device layer and the light-emitting device, wherein the bonding layer includes several bonding points corresponding to each of the CMOS devices, the bonding points are bonded correspondingly to the first electrode of each light-emitting area in the light-emitting device.

As mentioned above, the light-emitting device, the manufacturing method thereof and the display screen of the present disclosure have the following advantageous effects:

In the light-emitting device of the present disclosure, an isolation trench is formed from the first semiconductor layer to one side of the second semiconductor layer, and a reflective structure is formed on the sidewall of the isolation trench and on the first semiconductor layer, which helps to reduce light loss and improve the light output efficiency of the device. In addition, the isolation trench does not completely penetrate the second semiconductor layer, so that the second semiconductor layer on one side of the light output surface has a continuous and uninterrupted integrated structure, and the surface thereof remains flat so that the transparent conductive layer formed thereon also has a flat structure, thus improving the overall coverage of the transparent conductive layer and avoiding problems such as cracks and peeling. In this way, it is possible to improve the electrical stability of the device as well as reliability thereof.

### BRIEF DESCRIPTION OF THE DRAWINGS

FIG. 1 shows a schematic structural diagram of a display screen in the conventional technology.

FIG. 2A shows a schematic structural diagram of a light-emitting device provided in Embodiment 1 of the present disclosure.

FIG. 2B shows a schematic structural diagram of a light-emitting device provided as an optional embodiment of Embodiment 1 of the present disclosure.

FIG. 3 shows a flow chart of a manufacturing method of the light-emitting device shown in FIG. 2A.

FIG. 4 shows a schematic diagram of forming an epitaxial structure and a transparent conductive layer on a growth substrate.

FIG. 5 shows a schematic diagram of forming a step structure at the edge of the structure shown in FIG. 4.

FIG. 6 shows a schematic structural diagram of a temporary substrate bonded over the structure shown in FIG. 5.

FIG. 7 shows a schematic structural diagram of the structure after removing the growth substrate.

FIG. 8 shows a schematic structural diagram of forming first electrodes on the first semiconductor layer structure shown in FIG. 7.

FIG. 9 shows a schematic structural diagram of an isolation trench formed on the basis of the structure shown in FIG. 8.

FIG. 10 shows a schematic structural diagram of forming the first reflective structure in the structure shown in FIG. 9.

FIG. 11 shows a schematic diagram of filling a third dielectric layer on the structure shown in FIG. 10.

FIG. 12 shows a schematic structural diagram of a display screen provided in Embodiment 2 of the present disclosure.

FIG. 13 shows a schematic structural diagram of bonding a CMOS device layer to a light-emitting device.

FIG. 14 shows a schematic structural diagram of a display screen provided in Embodiment 3 of the present disclosure.

### DESCRIPTION OF THE EMBODIMENTS

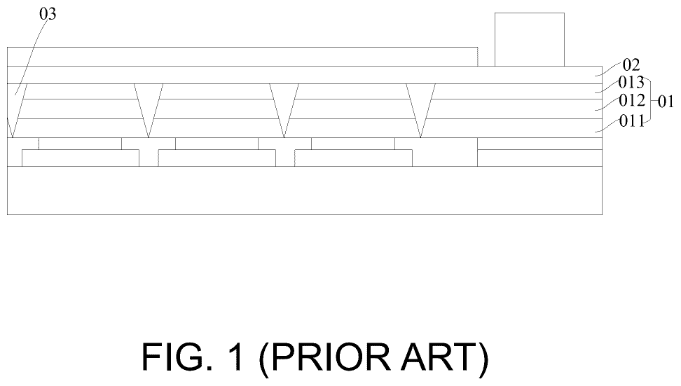

As shown in FIG. 1, in the conventional technology, when forming a monochromatic screen, the epitaxial layer 01 is normally cut from the light output surface downward, that is, the second semiconductor layer 011, the active layer 012 and the first semiconductor layer 013 are cut to form an isolation structure 03, thereby forming the epitaxial layer 01 into a plurality of separate chips, wherein the surface area of the light output surface side of a single chip is less than or equal to the surface area of one side opposite to the light output surface. However, since the side opposite to the light output surface is configured for disposing metal electrodes, there will inevitably be a problem of light absorption. When the chip size becomes smaller and smaller, almost all the area of the side opposite to the light output surface is occupied by metal electrodes, leaving no space for a reflective layer, which causes a great loss in brightness.

In addition, since the chips are separated from the light output surface as mentioned above, the gap filling process between the chips is difficult, and different levels of height differences are prone to occur. In that case, the entire coverage of the transparent conductive layer 02 (such as the ITO layer) on the surface of the second semiconductor layer cannot be ensured, and cracks might occur easily, which affects the reliability of the device.

### Embodiment 1

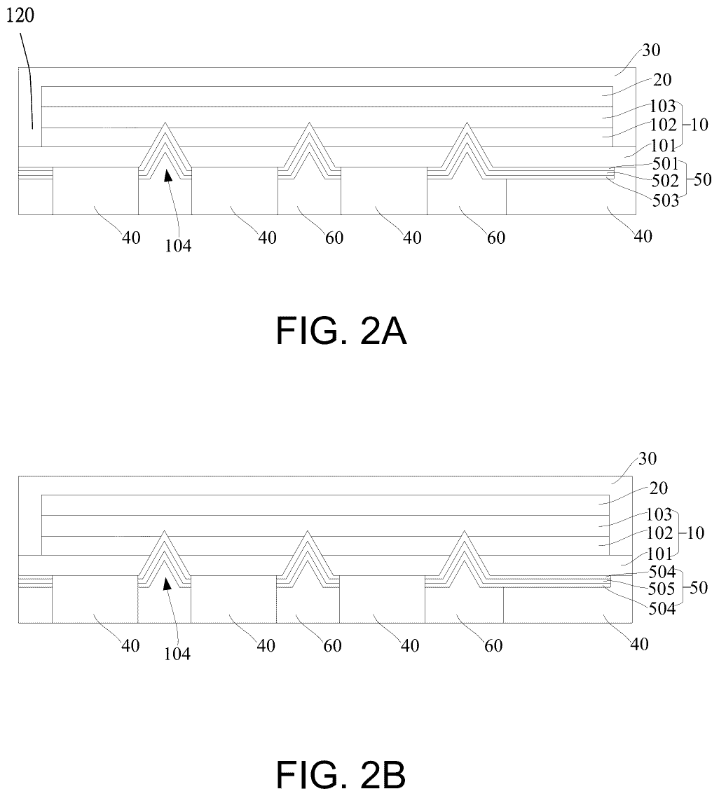

In order to solve the above-mentioned problems existing in monochromatic screen in the conventional technology, the embodiment provides a light-emitting device. As shown in FIG. 2A, the light-emitting device at least includes an epitaxial structure 10, and a plurality of isolation trenches 104 formed in the epitaxial structure 10, and a first reflective structure 50. The epitaxial structure 10 at least includes a first semiconductor layer structure 101, an active layer 102, and a second semiconductor layer structure 103 stacked in sequence; the epitaxial structure 10 is an epitaxial structure 10 capable of radiating light under the action of voltage. In this embodiment, the on epitaxial structure 10 is preferably an AlGaInP-based epitaxial structure. The above-mentioned first semiconductor layer structure 101 or the second semiconductor layer structure 103 may both be used as the light output surface side of the light-emitting device. In this embodiment, one side of the second semiconductor layer structure 103 is the light output surface side, and the side of the first semiconductor layer structure 101 opposite to the light output side is the bonding surface for bonding the light-emitting device and the control device, which are described as an example.

The above-mentioned first semiconductor layer structure 101 may be an N-type layer, and correspondingly, the second semiconductor layer structure 103 may be a P-type layer, or vice versa. In this embodiment, the first semiconductor layer structure 101 is an N-type layer and the second semiconductor layer structure 103 is a P-type layer, which are described as an example.

In an optional embodiment, the first semiconductor layer structure 101 is an N-type AlInP layer, configured to provide electrons. The N-type AlInP layer provides electrons by doping n-type impurities. The n-type impurities may be, for example, Si, Ge, Sn, Se, Te, etc. In this embodiment, the n-type impurity is preferably Si, and the Si doping concentration is 1×10¹⁸ Atoms/cm³ to 2×10¹⁸ Atoms/cm³ to provide electrons for radiation recombination. The second semiconductor layer structure 103 is a P-type AlInP layer, which is doped with P-type impurities to provide holes. The P-type impurities may be Mg, Zn, Ca, Sr, C, Ba, etc. In this embodiment, the P-type impurity is preferably Mg or C.

Referring also to FIG. 2A, a plurality of isolation trenches 104 penetrate the first semiconductor layer structure 101, the active layer 102 and part of the second semiconductor layer structure 103 in sequence in the stacking direction of the epitaxial layer 01. Adjacent isolation trenches divide the epitaxial layer 01 into multiple light-emitting areas, and the area between the isolation trenches 104 is the light-emitting area. The second semiconductor layer structure 103 is not completely penetrated by the isolation trench 104, and the continuous surface side of the second semiconductor layer structure 103 that is not penetrated serves as the light output surface. As shown in FIG. 2A, the opening width of the isolation trench 104 is greater than the bottom width of the isolation trench 104, that is, the opening width of the isolation trench 104 on one side of the first semiconductor layer structure 101 is greater than the width of the bottom in the second semiconductor layer structure 103. Preferably, the bottom of the isolation trench 104 is a point, that is, the isolation trench 104 is formed as a tapered hole. In an optional embodiment, the angle between the sidewall of the isolation trench 104 and the surface of the second semiconductor layer structure 103 is between 30° and 60°. The above-mentioned structure of the isolation trench 104 makes the surface area (top surface area) of the light output surface side of each light-emitting area larger than the surface area (bottom surface area) of the bonding surface side, thereby increasing the area of the light output surface to a certain extent, and improving the light output efficiency of the device as well.

A transparent conductive layer 20 is formed on the continuous flat surface of the second semiconductor layer structure 103. The transparent conductive layer 20 may serve as a transparent electrode connected to the second semiconductor layer structure 103, the first electrodes 40 are formed on one side of the first semiconductor layer 101 in an area opposite to the light-emitting area. The first electrodes 40 may be a metal layer or alloy layer such as Ti, Pt, Au, Ge, Ni, etc. The transparent conductive layer 20 may optionally be a transparent metal oxide layer, for example, a transparent metal oxide layer such as ITO or IZO. In this embodiment, the transparent conductive layer 20 is an ITO layer. As described above, the transparent conductive layer 20 covers the entire surface of the flat and continuous second semiconductor layer structure 103. Since the surface of the second semiconductor layer structure 103 is a flat surface with no height difference, the transparent conductive layer 20 has good coverage and will not have cracks, climbing difficulties, etc., which helps to improve the stability of the device. Also as shown in FIG. 2A, a step 120 is formed in the edge area of the epitaxial structure 10 of the light-emitting device. An insulating protective layer 30 is formed on the surface of the step 120, the sidewall of the epitaxial structure 10 and the surface of the second semiconductor layer structure 103. As shown in FIG. 2A, the first reflective structure 50 is formed on the sidewall of the isolation trench 104 and the first semiconductor layer structure 101, that is, the reflective structure covers the sidewall of the isolation trench 104 and surfaces of the first semiconductor layer structure 101 without the first electrodes 40 disposed thereon. The reflective structure significantly increases the reflection of light and improves the light output efficiency of the device. Optionally, the first reflective structure 50 includes a first dielectric layer 501, a metal layer 502 and a second dielectric layer 503. The first dielectric layer 501 covers the sidewall of the isolation trench 104 and areas on the first semiconductor layer without the first electrodes 40 disposed thereon; the metal layer 502 is formed on the first dielectric layer 501 and together with the first dielectric layer 501 forms a total reflection structure to ensure the reflection effect with respect to light. The metal layer 502 may be one or more alloys of Ag, Al, Cu, Sn, Au, etc. The metal layer 502 may cover the first electrodes 40, or may be formed around the first electrodes 40 without contacting the first electrodes 40. The second dielectric layer 503 covers the metal layer 502, serving as a part of the first reflective structure 50 on the one hand, and on the other hand serving protection function for the metal layer 502 of the first reflective structure 50. When the metal layer 502 covers the first electrodes 40, the second dielectric layer 503 covers the outside of the area corresponding to the first electrodes 40 and does not form part of the metal layer 502 covering the first electrodes 40 to ensure that a bonding electrode is formed in the area corresponding to the first electrodes 40. When the metal layer 502 is not in contact with the first electrodes 40, the second dielectric layer 503 is also formed in the gap between the first electrodes 40 and the metal layer 502 to better protect the metal layer 502 and ensure the insulation between the metal layer 502 and the first electrodes 40.

In an optional embodiment, as shown in FIG. 2B, the first reflective structure 50 serves as a DBR (distributed Bragg reflector) structure. The DBR structure is formed by alternately stacking the first insulating material layer 504 and the second insulating material layer 505. Optionally, the first insulating material layer 504 and the second insulating material layer 505 may be a SiO₂ layer and a TiO₂ layer respectively. FIG. 2B only illustrates the alternately stacked first insulating material layer 504 and the second insulating material layer 505. It may be understood that the number of the first insulating material layer 504 and the second insulating material layer 505 in the DBR structure may be set according to the actual situation, for example, there may be 3 to 15 pairs of the first insulating material layer 504 and the second insulating material layer 505. The above-mentioned DBR structure also covers the sidewall of the isolation trench 104 and surfaces of the first semiconductor layer structure 101 without the first electrodes 40 disposed thereon. Such configuration increases the reflection of light and improves the light output efficiency of the device. In the meantime, since the above-mentioned DBR structure is formed of an insulating material, the insulation between adjacent first electrodes is achieved simultaneously. Therefore, when the device is subsequently bonded to the control device, a single light-emitting area may be controlled individually, which helps to improve the display effect of the device.

In an optional embodiment, the light-emitting device further includes a second reflective structure formed in the first semiconductor layer structure 101. Specifically, the above-mentioned first semiconductor layer structure 101 includes a first contact layer, a first covering layer and a second reflective structure. The first contact layer is located on one side of the first semiconductor layer structure 101 away from the active layer 102; the first covering layer is located on one side of the first semiconductor layer structure 101 close to the active layer 102; the second reflective structure is located between the first contact layer and the first covering layer. Optionally, the first contact layer is a GaAs layer, which forms ohmic contact with the electrode material when the first electrodes 40 are formed subsequently. The second reflective layer optionally forms a DBR structure, for example, a DBR structure formed by alternately stacking AlInP and AlGaInP. The above-mentioned first covering layer is optionally an N-type AlInP layer. By replacing the conventional window layer with a second reflective structure in the first semiconductor layer structure 101, it is possible to improve the reflection of light and increase the light output efficiency of the device.

In an optional embodiment, a bonding electrode is also formed on the first electrodes 40, and the surface area of the bonding electrode may be greater than or equal to the surface area of the first electrode 40 to facilitate subsequent bonding with the control device.

In another optional embodiment, the third dielectric layer 60 is filled in the area between the isolation trench 104 and adjacent light output areas (specifically, between the first electrodes 40 or the bonding electrodes), and a flat surface is formed on one side of the bonding surface of the light-emitting device after the third dielectric layer 60 is filled. In this way, it is possible to protect the light-emitting device from external water vapor, impurities, etc., and thus improving the reliability of the device.

The above-mentioned first dielectric layer 501, the second dielectric layer 503 and the third dielectric layer 60 are all insulating material layers, and they may be the same material layer or different material layers, for example, they may be one of SiO₂, SiN, SiON, TiO₂, etc. or a combination of any ones of the above.

In an optional embodiment, any dielectric layer may not be filled between the isolation trench 104 and the adjacent light-emitting areas, that is, the uneven surface structure thereof may be retained. Under the circumstances, after the device and the control device are bonded, an air layer will be formed between one side of the bonding surface and the device layer.

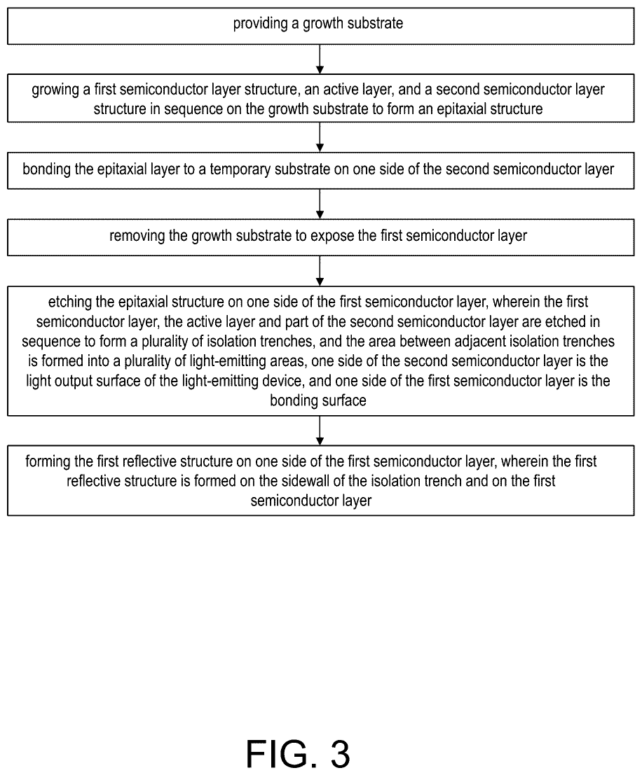

The present embodiment further provides a method for manufacturing the above-mentioned light-emitting device. The present embodiment takes the light-emitting device shown in FIG. 2A as an example for explanation. As shown in FIG. 3, the manufacturing method includes the following steps.

S100: A growth substrate is provided.

S200: A first semiconductor layer structure, an active layer, and a second semiconductor layer structure are grown in sequence on the growth substrate to form an epitaxial structure.

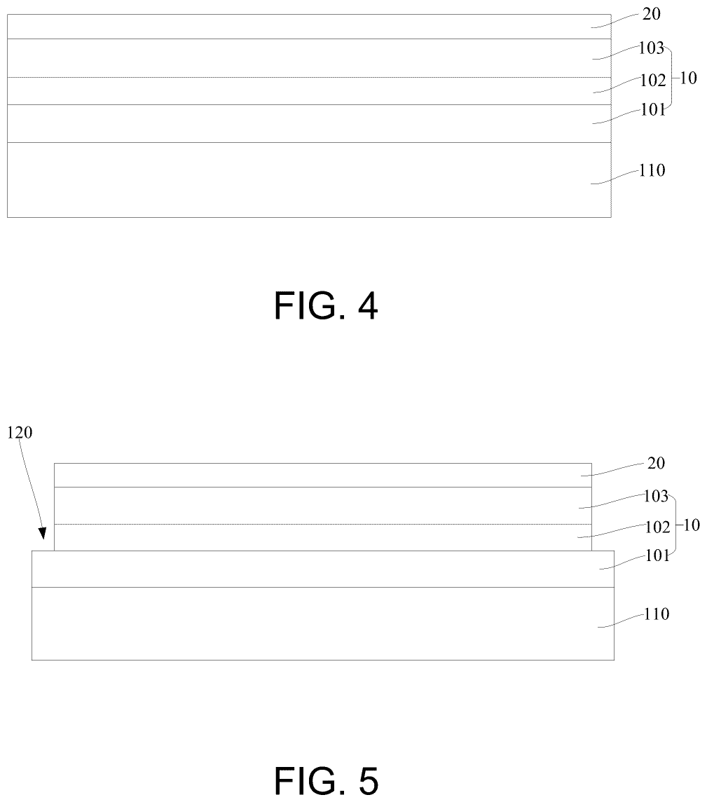

Referring to FIG. 4, a growth substrate 110 is first provided. The growth substrate 110 may be any substrate suitable for epitaxy, such as a Si substrate, a SiC substrate, a sapphire substrate, a GaAs substrate, etc. In this embodiment, a GaAs substrate is adopted.

Epitaxial growth is performed on the front side of the GaAs substrate, and the first semiconductor layer structure 101, the active layer 102 and the second semiconductor layer structure 103 are grown in sequence to form the epitaxial structure 10. The first semiconductor layer structure 101 in the present embodiment is an N-type semiconductor layer, wherein the doped N-type impurity is preferably Si to provide radiative recombination of electrons. The second semiconductor layer structure 103 is a P-type semiconductor layer, and the doped P-type impurities may be Mg, Zn, Ca, Sr, C, Ba, etc.

In an optional embodiment, when forming the above-mentioned first semiconductor layer structure 101, a first contact layer, a second reflective structure and a first covering layer are formed in sequence. Optionally, the first contact layer is a GaAs layer, which forms ohmic contact with the electrode material when the first electrodes 40 are formed subsequently. The second reflective structure optionally forms a DBR structure, for example, a DBR structure formed by alternately stacking AlInP and AlGaInP. The above-mentioned first covering layer is optionally an N-type AlInP layer. By replacing the conventional window layer with a second reflective structure in the first semiconductor layer structure 101, it is possible to improve the reflection of light and increase the light output efficiency of the device.

After the second semiconductor layer structure 103 is formed, a transparent conductive layer 20 is formed on the second semiconductor layer structure 103. The transparent conductive layer 20 may optionally be a transparent metal oxide layer, such as a transparent metal oxide layer like ITO or IZO. In the present embodiment, the transparent conductive layer 20 is an ITO layer. As described above, the transparent conductive layer 20 covers the entire surface of the flat and continuous second semiconductor layer structure 103.

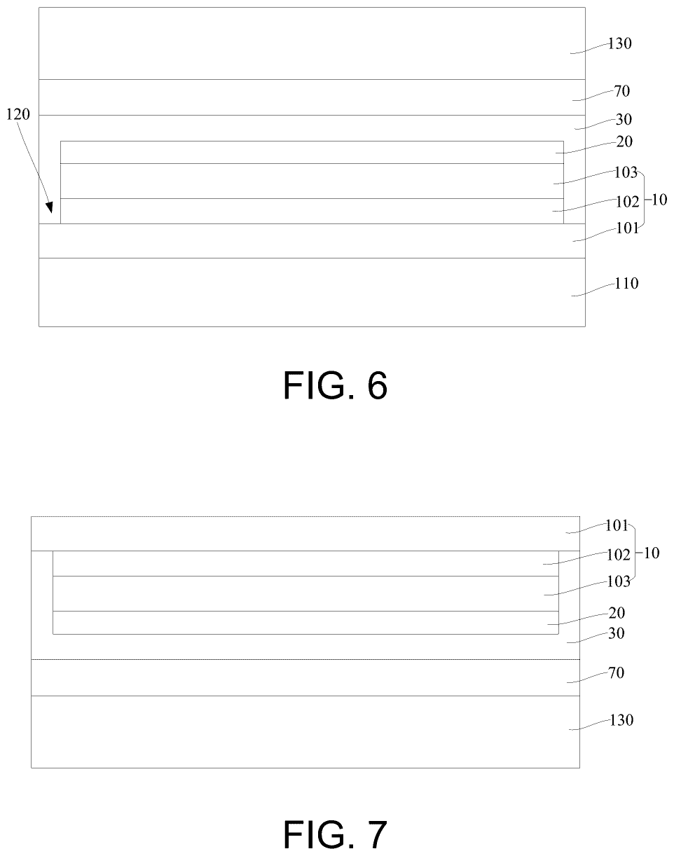

Referring to FIG. 5, after forming the epitaxial structure 10 and the transparent conductive layer 20, the transparent conductive layer 20 and the epitaxial structure 10 are etched along the edge of the epitaxial layer, and the etching stops until the first semiconductor layer is etched, thereby forming a step 120 in the edge area. With reference to FIG. 6 in conjunction, an insulating protective layer 30 is formed on the etched surface of the step 120 as well as the sidewall of the epitaxial structure 10 and the surface of the second semiconductor layer structure 103.

S300: The epitaxial layer is bonded to a temporary substrate on one side close to the second semiconductor layer.

Referring to FIG. 6, one side close to the second semiconductor layer structure 103 is bonded to a temporary substrate 130, for example, bonded to a sapphire substrate through a B adhesive 70 as the temporary substrate 130.

S400: The growth substrate is removed to expose the first semiconductor layer.

Then, as shown in FIG. 7, the structure shown in FIG. 6 is inverted, with the temporary substrate 130 on the bottom and the epitaxial structure 10 on the top. The growth substrate 110 is then removed, for example, the substrate 110 is peeled off by laser ablation or the like. The first semiconductor layer structure 101 of the epitaxial structure 10 is exposed after the substrate is peeled off. Specifically, the first contact layer of the first semiconductor layer structure 101 is exposed.

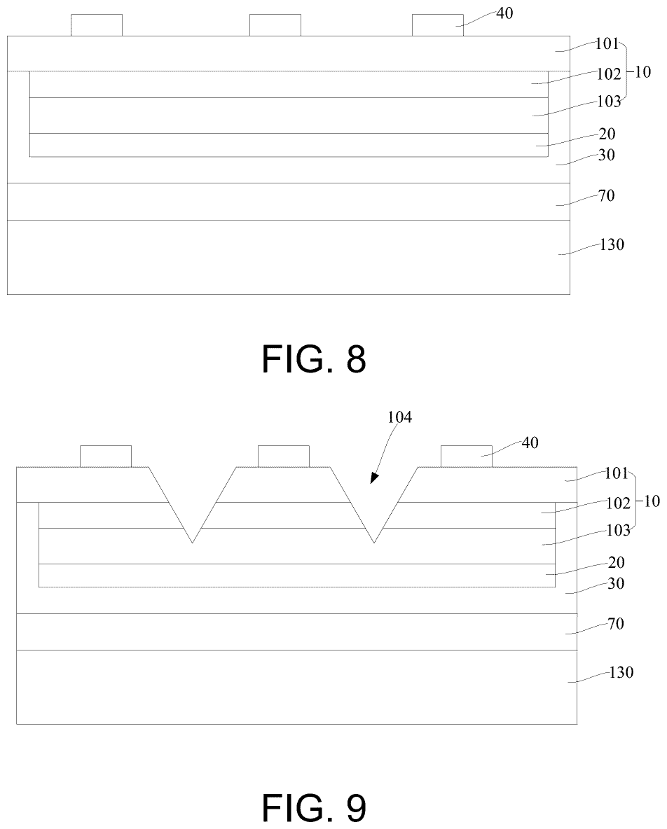

After the first semiconductor layer structure 101 is exposed, as shown in FIG. 8, the first electrodes 40 are formed on the surface of the first semiconductor layer structure 101. The first electrodes 40 serve as a contact electrode and is connected to a subsequently formed bonding electrode. Optionally, the first electrodes 40 are a metal layer or alloy layer such as Ti, Pt, Au, etc.

S500: The epitaxial structure is etched on one side of the first semiconductor layer, and the first semiconductor layer, the active layer and part of the second semiconductor layer structure are etched in sequence to form a plurality of isolation trenches 104. The areas between the isolation trenches 104 serve as a plurality of light-emitting areas, one side of the second semiconductor layer is the light output surface of the light-emitting device, and one side of the first semiconductor layer is the bonding surface.

As shown in FIG. 9, the epitaxial structure 10 is etched from one side of the first semiconductor layer structure 101 to form a plurality of isolation trenches 104. Specifically, the first semiconductor layer structure 101, the active layer 102 and part of the second semiconductor layer structure 103 are etched in sequence, and the etching is stopped in the second semiconductor layer structure 103, and the second semiconductor layer structure 103 is not completely etched. Adjacent isolation trenches divide the epitaxial layer into multiple light-emitting areas, and the area between the isolation trenches 104 is the light-emitting area. The second semiconductor layer structure 103 is not completely penetrated by the isolation trench 104, and the continuous surface of the second semiconductor layer structure 103 that is not penetrated serves as the light output surface. As shown in FIG. 9, the opening width of the isolation trench 104 is greater than the bottom width of the isolation trench 104, that is, the opening width of the isolation trench 104 on one side of the first semiconductor layer structure 101 is greater than the width of the bottom in the second semiconductor layer structure 103. Preferably, the bottom of the isolation trench is a point, that is, the isolation trench 104 is formed as a tapered hole. In an optional embodiment, the angle between the sidewall of the isolation trench 104 and the surface of the second semiconductor layer structure 103 is between 30° and 60°. The above-mentioned structure of the isolation trench 104 makes the surface area of the light output surface side of each light-emitting area larger than the surface area of the bonding surface side, thereby increasing the area of the light output surface to a certain extent, and improving the light output efficiency of the device as well. In addition, since the isolation trench 104 has not completely etched through the second semiconductor layer structure 103, the surface of the second semiconductor layer structure 103 is a flat surface with no level difference. Therefore, the transparent conductive layer 20 has good coverage and has no cracks or climbing difficulties, etc., thereby improving the stability of the device.

S600: A first reflective structure is formed on one side of the first semiconductor layer, and the first reflective structure is formed on the sidewall of the isolation trench and the first semiconductor layer.

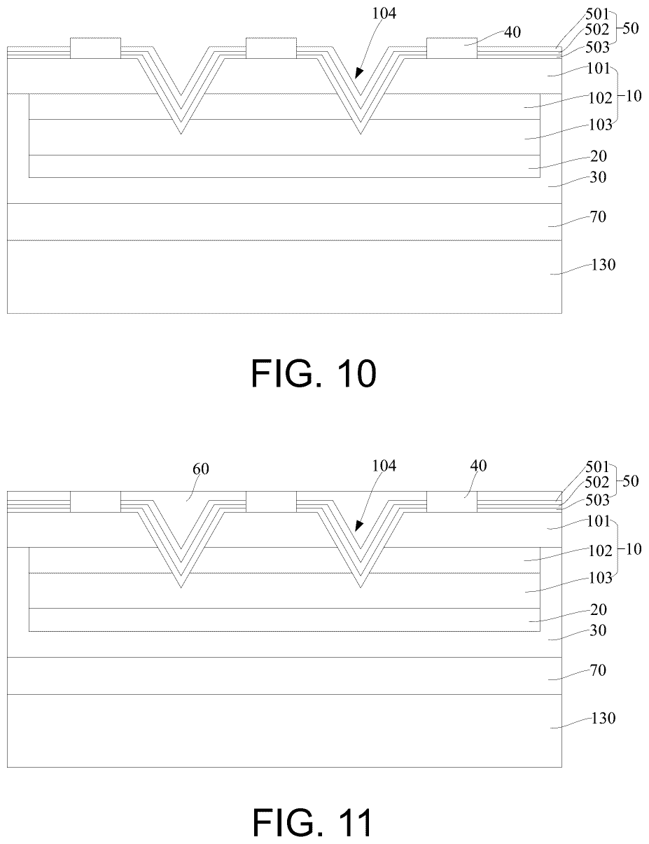

As shown in FIG. 10, a first reflective structure 50 is formed on the sidewall of the isolation trench 104 and the first semiconductor layer structure 101. That is, the first reflective structure 50 covers the sidewall of the isolation trench 104 and surfaces of the first semiconductor layer structure 101 without the first electrodes 40 disposed thereon. The reflective structure significantly increases the reflection of light and improves the light output efficiency of the device. Specifically, the first dielectric layer 501, the metal layer 502 and the second dielectric layer 503 are deposited in sequence on the sidewall of the isolation trench 104 and surfaces of the first semiconductor layer structure 101 without the first electrodes 40 disposed thereon. The first dielectric layer 501 covers the sidewall of the isolation trench 104 and areas on the first semiconductor layer structure 101 without the first electrodes 40 disposed thereon; the metal layer 502 is formed on the first dielectric layer 501 and together with the first dielectric layer 501 forms a total reflection structure to ensure the reflection effect of light. The metal layer 502 may be one or more alloys of Ag, Al, Cu, Sn, Au, etc. The metal layer 502 may cover the first electrodes 40, or may be formed around the first electrodes 40 without contacting the first electrodes 40. The second dielectric layer 503 covers the metal layer 502, serving as a part of the reflective structure on the one hand, and on the other hand serving protection function for the metal layer 502 of the first reflective structure 50. When the above-mentioned metal layer 502 covers the first electrodes 40, the second dielectric layer 503 covers the outside of the area corresponding to the first electrodes 40 and is not formed on the part of the metal layer 502 covering the first electrodes 40. In this way, it is possible to ensure that a bonding electrode is formed in an area corresponding to the first electrode 40 subsequently. When the metal layer 502 is not in contact with the first electrodes 40, the second dielectric layer 503 is also formed in the gap between the first electrodes 40 and the metal layer 502 to better protect the metal layer 502 while ensuring the insulation between the metal layer 502 and the first electrodes 40.

As shown in FIG. 11, after the above-mentioned first reflective structure 50 is formed, the third dielectric layer 60 is filled on one side close to the bonding surface, that is, the third dielectric layer 60 is filled in the isolation trench 104 and between the adjacent first electrodes 40. The surface of the third dielectric layer 60 is aligned with the surface of the first electrode 40. Such configuration makes one side close to the bonding surface a flat surface, and helps to protect the light-emitting device from external water vapor, impurities, etc., and thus improving the reliability of the device.

After the above-mentioned third dielectric layer 60 is formed, the method further includes inverting the structure shown in FIG. 11 and removing the temporary substrate 130 to form the light-emitting device shown in FIG. 2A.

### Embodiment 2

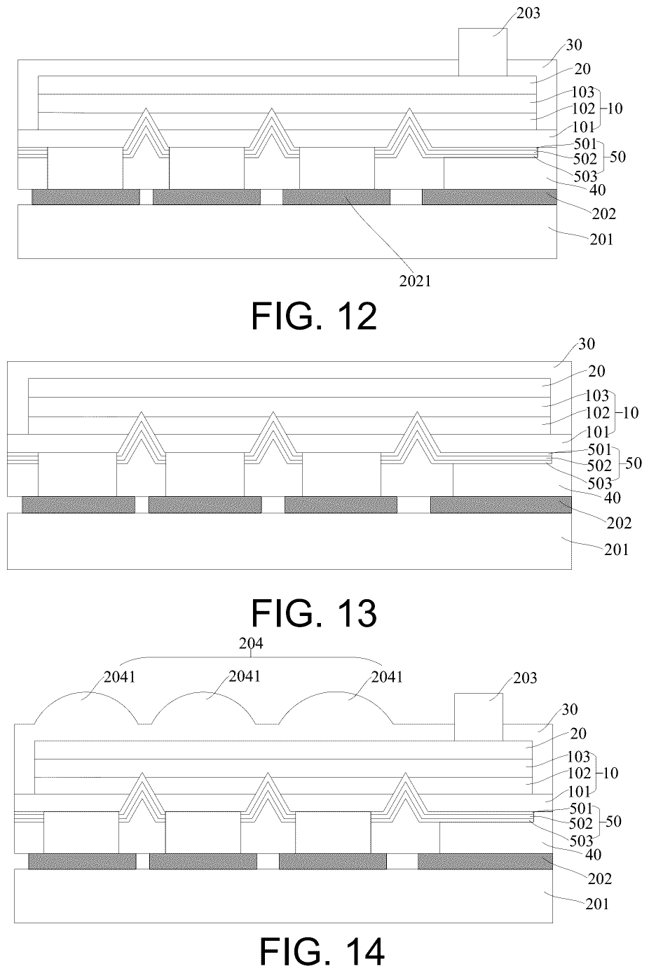

The present embodiment provides a display screen, which is a monochromatic display screen. As shown in FIG. 12, the display screen includes at least one light-emitting device CMOS substrate 201 and a bonding layer 202. The light-emitting device may be the light-emitting device provided in Embodiment 1. Several CMOS devices are formed on the CMOS substrate 201. The bonding layer 202 is located between the light-emitting device and the CMOS substrate 201 to bond the light-emitting device to the CMOS substrate 201. Specifically, the bonding layer 202 serves as several bonding points 2021, which are in one-to-one correspondence with the CMOS devices in the CMOS device layer, and are in one-to-one correspondence with the first electrode 40 (i.e., the bonding electrode) in the light-emitting device, thereby achieving a one-to-one correspondence between the CMOS device and the light-emitting area in the light-emitting device, thus realizing control of each light-emitting area. Optionally, the bonding points 2021 in the above-mentioned bonding layer 202 may be connected to each other, that is, the bonding layer 202 forms an integrated structure. In this case, multiple light-emitting areas of the light-emitting device may be controlled simultaneously through the CMOS device. Several bonding points 2021 in the bonding layer 202 may also be spaced apart and insulated from each other, that is, each bonding point 2021 is connected to one CMOS device and one light-emitting area, so that each light-emitting area may be controlled individually.

As shown in FIG. 12, the display screen further includes a bonding wire electrode 203. The bonding wire electrode 203 is located on one side of the light-emitting surface of the light-emitting device and is formed in an edge area outside the light-emitting area while being connected to the transparent conductive layer 20 of the light-emitting device.

The present embodiment also provides a manufacturing method for the above-mentioned display screen. As shown in FIG. 13, a CMOS substrate 201 is first provided, and several CMOS devices are formed on the CMOS substrate 201. Then, a bonding layer 202 is formed on one side of the CMOS device. The bonding layer 202 includes several bonding points 2021, wherein each bonding point 2021 is in one-to-one correspondence to each CMOS device. Then, one side of the bonding surface of the light-emitting device is bonded to the bonding layer 202. The first electrode 40 of the light-emitting device is in one-to-one correspondence to the bonding point 2021, thereby realizing a one-to-one correspondence between the light-emitting area in the light-emitting device and the bonding point 2021, and the CMOS device realizes control of the light-emitting area.

Optionally, the bonding points 2021 in the above-mentioned bonding layer 202 serve as an interconnected structure, that is, the bonding layer 202 forms an integrated structure. In this case, multiple light-emitting areas of the light-emitting device may be controlled simultaneously by a CMOS device.

Optionally, several bonding points 2021 in the bonding layer 202 are spaced apart from each other so that the bonding points 2021 are insulated from each other, that is, each bonding point 2021 is connected to one CMOS device and one light-emitting area, so that each light-emitting area may be controlled individually.

### Embodiment 3

The present embodiment also provides a display screen. As shown in FIG. 14, the display screen forms a lens array 204 on one side of the light output surface. The lens array 204 includes at least one lens structure 2041. The lens structure 2041 may be in one-to-one correspondence to the light-emitting area, and it may be that the entire display screen form a lens structure 2041, and the configuration may be selected depending on actual needs. The lens array 204 facilitates extraction of light and improves the display effect of the display screen.

What is claimed is:

1. A light-emitting device, comprising:
an epitaxial structure, wherein the epitaxial structure comprises a first semiconductor layer structure, an active layer, and a second semiconductor layer structure that are stacked in sequence;
a plurality of isolation trenches, wherein the plurality of isolation trenches penetrate the first semiconductor layer structure and the active layer along a stacking direction of the epitaxial structure, and the isolation trenches do not completely penetrate the second semiconductor layer structure; areas between the adjacent isolation trenches serve as a plurality of light-emitting areas, one side of the second semiconductor layer structure is a light output surface of the light-emitting device, and one side of the first semiconductor layer structure is a bonding surface; and
a first reflective structure, which is disposed one a sidewall of the plurality of isolation trenches and on the first semiconductor layer structure.

2. The light-emitting device according to claim 1, wherein a surface area of the light output surface is defined as a top surface area, a surface area of the bonding surface is a bottom surface area, and the top surface area is greater than the bottom surface area.

3. The light-emitting device according to claim 1, wherein a width of an opening of each of the plurality of isolation trenches is greater than a width of a bottom thereof.

4. The light-emitting device according claim 1, further comprising:
a plurality of first electrodes, respectively corresponding to the plurality of light-emitting areas, disposed on the first semiconductor layer structure and connected to the first semiconductor layer structure; and
a transparent conductive layer, covering a surface of the second semiconductor layer structure and having a flat surface, wherein the transparent conductive layer serves as a second electrode connected to the second semiconductor layer structure.

5. The light-emitting device according to claim 4, wherein the first reflective structure is a DBR (distributed Bragg reflector) structure and comprises a first insulating material layer and a second insulating material layer alternately stacked, the DBR structure is disposed on the sidewall of the plurality of isolation trenches and areas of the first semiconductor layer structure without the first electrodes disposed thereon.

6. The light-emitting device according to claim 4, wherein the first reflective structure comprises:
a first dielectric layer, disposed on the sidewall of the plurality of isolation trenches and areas of the first semiconductor layer structure without the first electrodes disposed thereon;
a metal layer, wherein the metal layer is formed on the first dielectric layer and covers the plurality of first electrodes; and
a second dielectric layer, formed on the metal layer and exposing the metal layer corresponding to the plurality of first electrodes.

7. The light-emitting device according to claim 4, wherein the first semiconductor layer structure comprises:
a first contact layer, disposed on one side of the first semiconductor layer structure away from the active layer;
a first covering layer, disposed on one side of the first semiconductor layer structure close to the active layer; and
a second reflective structure, disposed between the first contact layer and the first covering layer.

8. The light-emitting device according to claim 4, wherein a bonding electrode is formed on the plurality of first electrodes.

9. The light-emitting device according to claim 4, further comprising a third dielectric layer that fills the plurality of isolation trenches, and is disposed between the plurality of first electrodes, and is aligned with the plurality of first electrodes.

10. A method for manufacturing a light-emitting device, comprising the following steps:
providing a growth substrate;
growing a first semiconductor layer structure, an active layer, and a second semiconductor layer structure in sequence on the growth substrate to form an epitaxial structure;
bonding the epitaxial layer to a temporary substrate on one side of the second semiconductor layer structure;
removing the growth substrate to expose the first semiconductor layer structure;
etching the epitaxial structure on one side of the first semiconductor layer structure, wherein the first semiconductor layer structure, the active layer and part of the second semiconductor layer structure are etched in sequence to form a plurality of isolation trenches, and areas between the plurality of adjacent isolation trenches serve as a plurality of light-emitting areas, one side of the second semiconductor layer structure is a light output surface of the light-emitting device, and one side of the first semiconductor layer structure is a bonding surface;
forming a first reflective structure on the one side of the first semiconductor layer structure, wherein the first reflective structure is formed on a sidewall of the plurality of isolation trenches and on the first semiconductor layer structure.

11. The method for manufacturing the light-emitting device according to claim 10, wherein the step of forming the first reflective structure on the one side of the first semiconductor layer structure comprises the following steps:
forming a first dielectric layer, wherein the first dielectric layer covers the sidewall of the plurality of isolation trenches and areas of the first semiconductor layer structure without the first electrodes disposed thereon;
forming a metal layer, wherein the metal layer is formed on the first dielectric layer and covers the plurality of first electrodes;
forming a second dielectric layer, wherein the second dielectric layer is formed on the metal layer and exposes the metal layer corresponding to the plurality of first electrodes.

12. The method for manufacturing the light-emitting device according to claim 10, wherein the step of forming the first reflective structure on the one side of the first semiconductor layer structure further comprises the following steps:
alternately forming a first insulating material layer and a second insulating material layer to form a DBR structure, wherein the DBR structure is disposed on the sidewall of the plurality of isolation trenches and areas of the first semiconductor layer structure without the first electrodes disposed thereon.

13. The method for manufacturing the light-emitting device according to claim 10, wherein the step of growing the first semiconductor layer structure on the growth substrate comprises the following steps:
growing a first contact layer on the growth substrate;
forming a second reflective structure on the first contact layer; and
forming a first covering layer on the second reflective structure.

14. The method for manufacturing the light-emitting device according to claim 10, further comprising: forming a transparent conductive layer on the second semiconductor layer structure after forming the epitaxial structure, wherein the transparent conductive layer covers a surface of the second semiconductor layer structure and has a flat surface.

15. A display screen, comprising:
the light-emitting device according to claim 1;
a CMOS substrate comprising a device layer comprising a plurality of CMOS devices; and
a bonding layer disposed between the device layer and the light-emitting device, wherein the bonding layer comprises a plurality of bonding points, the plurality of bonding points respectively correspond to the plurality of CMOS devices and respectively correspond to the plurality of light-emitting areas in the light-emitting device.

16. The display screen according to claim 15, further comprising a lens structure formed on the light output surface of the light-emitting device and covering at least part of the plurality of light-emitting areas of the light-emitting device.

17. The display screen according to claim 15, further comprising a bonding wire electrode disposed on the light output surface of the light-emitting device, formed in an edge area outside the plurality of light-emitting areas, and connected to a transparent conductive layer of the light-emitting device.

18. The display screen according to claim 15, wherein the plurality of bonding points are insulated from each other, or the plurality of bonding points are connected to each other.
